(19) United States
(12) Patent Application Publication
(10) Pub. No.: US 2025/0226833 A1
(43) Pub. Date: Jul. 10, 2025

(54) CHANNEL AND ASSOCIATED CONDITIONING UNIT, CONDITION MONITORING SYSTEM

(71) Applicant: Aktiebolaget SKF, Göteborg (SE)

(72) Inventor: Fredrik SUNDQUIST, Luleå (SE)

(21) Appl. No.: 19/007,712

(22) Filed: Jan. 2, 2025

(30) Foreign Application Priority Data
Jan. 8, 2024 (DE) 102024200147.3

(51) Int. Cl. H03M 1/12; G01D 5/12

(52) U.S. Cl. CPC H03M 1/12; G01D 5/12

(57) ABSTRACT

A channel (14) for a conditioning unit is proposed. The channel includes at least a first terminal (7), a variable current source (15), and an analog-to-digital converter (16). The analog-to-digital converter (16) includes first and second connections so that an analog signal on a first connection is converted to a digital signal on the second connection. The first terminal (7) is connected to the variable current source (15) and the first connection of the analog-to-digital converter (16).

### CROSS-REFERENCE TO RELATED APPLICATION

This application claims priority to German Application No. 102024200147.3, filed Jan. 8, 2024, the entirety of which is hereby incorporated by reference.

### FIELD

The present disclosure is directed to channels for monitoring unit.

The present disclosure also relates to conditioning units comprising such channels.

### BACKGROUND

Generally, sensors are implemented on a machine to monitor the machine.

The sensors are connected to a conditioning unit.

The conditioning unit conditions signals delivered by the sensors so that the conditioned signals transmitted by the conditioning unit may be processed by control systems.

The sensors may output analog or digital signals so that the conditioning unit comprises analog and digital channels to communicate with different types of sensors and control systems.

Generally, all channel types are not used simultaneously so that terminals of the said channels are not used while additional devices may be needed to have the required number of a specific type of channels.

As the number of terminals of the channels mainly determine the size of the conditioning unit, the addition of at least one additional device increase the size of the conditioning unit.

Furthermore, the addition of additional devices creates variants of the conditioning unit.

Consequently, the present disclosure intends to improve the flexibility of the channels of the condition monitoring to reduce the number of additional devices.

### SUMMARY

According to an aspect, a channel for a conditioning unit is proposed. The channel comprises at least a first terminal, a variable current source, and an analog-to-digital converter. The analog-to-digital converter comprises first and second connections so that an analog signal on the first connection is converted to a digital signal on the second connection. The first terminal is connected to the variable current source and the first connection of the analog-to-digital converter.

The terminals of the channel may act as analog or digital inputs and outputs to optimize the usability of the channel avoiding adding additional devices known from the prior art.

Advantageously, the channel comprises a second terminal and a switch including a first end and a second end intended to be connected to a ground, the second terminal being connected to the first end of the switch, the analog-to-digital converter comprising a third connection connected to the second terminal.

Preferably, the channel comprises a supply terminal intended to be connected to a constant voltage source.

Advantageously, the variable current source comprises a variable current generator intended to be supplied by the constant voltage source.

Preferably, the channel further comprises a digital to analog converter including first and second connections so that a digital signal on the first connection is converted to an analog signal on the second connection, the second connection being connected to a control input of the variable current generator.

Advantageously, the channel further comprises comparison means configured to deliver a high logic state when the amplitude of a signal on one terminal is equal or bigger than a threshold and to deliver a low logic state when the amplitude of the signal is smaller than the threshold.

Preferably, the comparison means comprise a comparator comprising a same number of input as the number of terminal, each input being connected to a terminal, the high logic state or the low logic state being delivered on the output.

Preferably, the channel further comprises checking means configured to detect that a signal is circulating on the first terminal and the second terminal.

In another aspect, a conditioning unit is proposed.

The conditioning unit comprises at least one channel as defined above.

In another aspect, a conditioning monitoring system is proposed.

The conditioning monitoring comprises at least one sensor intended to be secured onto a machine and a conditioning unit as defined above, the sensor being connected to the first or second terminal.

Preferably, the sensor is connected to the first terminal, the variable current source supplying the sensor.

In another aspect, a conditioning system comprising a conditioning unit as defined above is proposed.

### BRIEF DESCRIPTION OF THE DRAWINGS

Other advantages and features of the present disclosure will appear on examination of the detailed description of embodiments, in no way restrictive, and the appended drawings in which:

FIG. 1 illustrates schematically a machine according to the present disclosure; and

FIG. 2 illustrates schematically an example of a conditioning unit according to the present disclosure.

### DETAILED DESCRIPTION

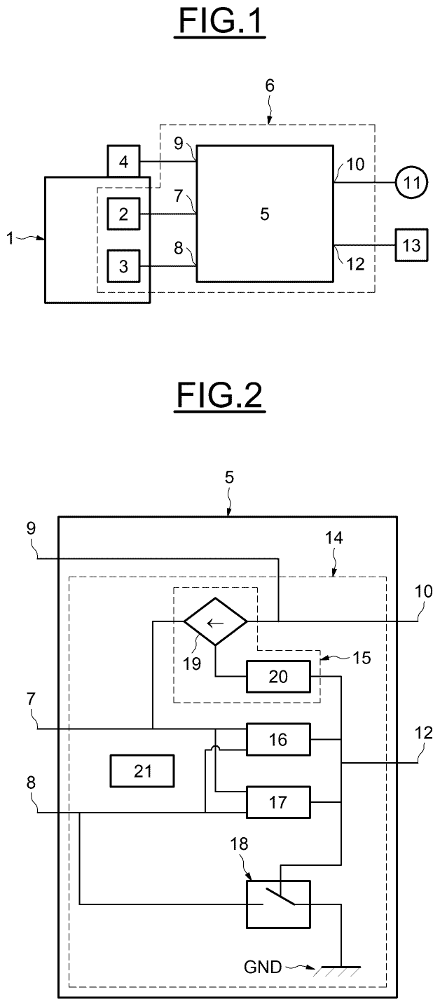

Reference is made to FIG. 1 which represents schematically a machine 1.

The machine 1 comprises sensors 2, 3 secured onto the machine 1 to monitor the machine 1.

A first sensor 2 may be a temperature sensor to measure the temperature of the machine 1 and a second sensor 3 may be a vibration sensor to measure vibration of the machine.

A device 4 may be fixed on the machine 1 for example a wireless transmitter.

The sensors 2, 3 and the device 4 are connected to a conditioning unit 5.

The sensors 2, 3 and the conditioning unit 5 form a conditioning monitoring system 6.

The conditioning unit 5 comprises a first terminal 7 connected to the first sensor 2, a second terminal 8 connected to the second sensor 3, and a supply terminal 9 connected to the device 4.

The conditioning unit 5 further comprises an input 10 connected to a constant voltage source 11, and a control bus 12 connected to a control device 13.

The constant voltage source 11 delivers for example 24 V.

FIG. 2 illustrates schematically an example of the conditioning unit 5.

The conditioning unit 5 comprises a channel 14 extending between the first terminal 7, the second terminal 8, the input 10, and the control bus 12.

The channel 14 comprises a variable current source 15, an analog-to-digital converter (ADC) 16.

The channel 14 may further comprise comparison means comprising for example a comparator 17.

The channel 14 may comprise a switch 18.

The variable courant source 15 may comprise a variable current generator 19 comprising an input connected to the input 10 of the conditioning unit 5, an output connected to the first terminal 7, and a control input.

The variable current source 15 may further comprise a second ADC 20 controlling the variable current generator 19.

The second ADC 20 comprises a first connection connected to the control bus 12 of the conditioning unit 5 and a second connection connected to the control input of the variable current generator 19.

The second ADC 20 converts a digital signal delivered by the control device 13 to an analog signal controlling the variable current generator 19.

The variable current generator 19 may for example deliver a current between 0 and 20 mA.

The ADC 16 comprises a first connection connected to the first terminal 7, a second connection connected to the control bus 12 of the conditioning unit 5 and a third connection connected to the second terminal 8.

The ADC 16 converts an analog signal received on one of the first and third connections to a digital signal delivered on the second connection.

The comparator 17 comprises a first input connected to the first terminal 7 and a second input connected to the second terminal 8.

The comparator 17 further comprises an output connected to the control bus 12 of the conditioning unit 5.

The comparator 17 is intended to deliver a high logic state, for example a logical “1” on the output when the amplitude of a signal on the first input or second input is equal or bigger than a threshold, and to deliver a low logic state, for example logical “0” when the amplitude of the signal is smaller than the threshold.

In another embodiment, the comparison means may be in the control device 13, the comparison means being for example an algorithm implemented by the control device 13.

The comparison means in the control device 13 is intended to deliver the high logic state when the amplitude of a signal on the first or third connection of the ADC 16 is equal or bigger than the threshold, and to deliver the low logic state when the amplitude of the signal on the first or third connection of the ADC 16 is smaller than the threshold.

The comparison means may comprise hysteresis comparison means to avoid untimely toggling of the comparison means.

The switch 18 comprises a first end connected to the second terminal 8 and a second end connected to a ground GND.

A control input of the switch 18 is connected to the control bus 12 of the conditioning unit 5 so that the control device 13 controls the switch 18.

The channel 14 may further comprise checking means 21 intended to detect that a signal is circulating on the first terminal 7 and on the second terminal 8.

The supply terminal 9 is connected to the input of the conditioning unit 5 to supply the device 4.

The conditioning unit 5 may comprise more than one channel.

The different configurations of the first and second terminals 7, 8 are explained in the following.

In a first configuration of the channel 14, the first terminal 7 supplies a device connected to the first terminal 7 with current delivered by the variable current source 15.

In a second configuration of the channel 14, the first terminal 7 acts as an analog output, the variable current source 15 delivering a variable current so that the waveform of the current reproduces the wave form of an analog signal.

In a third configuration of the channel 14, the first terminal 7 acts as a digital output, the variable current source 15 delivering a first current having a value so that the delivered signal is interpreted as the high logic state, for example a logical “1”, and a second current having a value so that the delivered signal is interpreted as the low logic state, for example a logical “0”.

In a fourth configuration of the channel 14, the first terminal 7 acts as an analog input. An analog signal circulating on the first terminal 7 is converted in a digital signal by the ADC 16, the checking means 21 checking that a signal is circulating on the first terminal 7.

In a fifth configuration of the channel 14, the first terminal 7 acts as a digital input delivering the result of the comparison made by the comparison means.

In a sixth configuration of the channel 14, the second terminal 8 acts as a digital input delivering the result of the comparison made by the comparison means.

In a seventh configuration of the channel 14, the second terminal 8 acts as an analog input. An analog signal circulating on the second terminal 8 is converted in a digital signal by the ADC 16, the checking means 21 checking that a signal is circulating on the second terminal 8.

In an eighth configuration of the channel 14, the second terminal 8 acts as an on/off switch to supply a device connected to the second terminal 8, the said device being for example supplied by the second and supply terminals 8, 9. The switch 18 switches on or off the said device.

Only one terminal of the first and second terminals 7, 8 may be operated.

In variant, the first terminal 7 may operate according to one of the first to fifth configurations and the second terminal 8 may simultaneously operate according to one of the sixth to eighth configurations.

The conditioning unit 5 may further be implemented in a conditioning system.

Each terminal of the terminals 7, 8 of the channel 14 may act as analog or digital inputs and outputs to optimize the usability of the channel 14 avoiding to add additional devices known from the prior art.

As no additional devices are needed, the conditioning unit 5 is more compact so that the space needed to implement the said unit 5 is decreased.

The terminals 7 and 8 acting as digital inputs may be used to measure the frequency of a digital input signal.

What is claimed is:

1. A channel for a conditioning unit, the channel comprising:
a first terminal;
a variable current source; and
an analog-to-digital converter comprising first and second connections so that an analog signal on the first connection is converted to a digital signal on the second connection;
the first terminal being connected to the variable current source and the first connection of the analog-to-digital converter.

2. The channel according to claim 1, further comprising a second terminal and a switch including a first end and a second end intended to be connected to a ground, the second terminal being connected to the first end of the switch, the analog-to-digital converter comprising a third connection connected to the second terminal.

3. The channel according to claim 1, further comprising a supply terminal intended to be connected to a constant voltage source.

4. The channel according to claim 3, wherein the variable current source comprises a variable current generator intended to be supplied by the constant voltage source.

5. The channel according to claim 1, further comprising comparison means configured to deliver a high logic state when the amplitude of a signal on one terminal is equal or bigger than a threshold and to deliver a low logic state when the amplitude of the signal is smaller than the threshold.

6. The channel according to claim 5, wherein comparison means comprise a comparator comprising a same number of input as the number of terminal, each input being connected to a terminal, the high logic state or the low logic state being delivered on the output.

7. The channel according to claim 1, further comprising checking means configured to detect that a signal is circulating on the first terminal.

8. The channel according to claim 1, in combination with the conditioning unit.

9. The channel according to claim 2, further comprising a supply terminal intended to be connected to a constant voltage source.

10. The channel according to claim 9, wherein the variable current source comprises a variable current generator intended to be supplied by the constant voltage source.

11. The channel according to claim 10, further comprising comparison means configured to deliver a high logic state when the amplitude of a signal on one terminal is equal or bigger than a threshold and to deliver a low logic state when the amplitude of the signal is smaller than the threshold.

12. The channel according to claim 11, wherein comparison means comprise a comparator comprising a same number of input as the number of terminal, each input being connected to a terminal, the high logic state or the low logic state being delivered on the output.

13. The channel according to claim 12, further comprising checking means configured to detect that a signal is circulating on the first terminal and the second terminal.

14. The channel according to claim 13, in combination with the conditioning unit.

15. A conditioning monitoring system comprising:
a conditioning unit;
a channel comprising:
a first terminal;
a variable current source;
an analog-to-digital converter comprising first and second connections so that an analog signal on the first connection is converted to a digital signal on the second connection, the first terminal being connected to the variable current source and the first connection of the analog-to-digital converter; and
checking means configured to detect that a signal is circulating on the first terminal; and
a sensor intended to be secured onto a machine, the sensor being connected to the first terminal.

16. A conditioning monitoring system comprising:
a conditioning unit;
a channel comprising:
a first terminal;
a variable current source comprising a variable current generator intended to be supplied by the constant voltage source;
an analog-to-digital converter comprising first and second connections so that an analog signal on the first connection is converted to a digital signal on the second connection, the first terminal being connected to the variable current source and the first connection of the analog-to-digital converter;
a second terminal;
a switch including a first end and a second end intended to be connected to a ground, the second terminal being connected to the first end of the switch, the analog-to-digital converter comprising a third connection connected to the second terminal;
a supply terminal intended to be connected to a constant voltage source;
comparison means configured to deliver a high logic state when the amplitude of a signal on one terminal is equal or bigger than a threshold and to deliver a low logic state when the amplitude of the signal is smaller than the threshold, the comparison means including a comparator comprising a same number of input as the number of terminal, each input being connected to a terminal, the high logic state or the low logic state being delivered on the output; and
checking means configured to detect that a signal is circulating on the first terminal and the second terminal; and
a sensor intended to be secured onto a machine, the sensor being connected to the first or second terminal.
